(19) United States
(12) Patent Application Publication
(10) Pub. No.: US 2012/0305940 A1
(43) Pub. Date: Dec. 6, 2012

(54) Defect Free Si:C Epitaxial Growth

(75) Inventors: Thomas N. Adam, Slingerlands, NY (US); Stephen W. Bedell, Wappingers Falls, NY (US); Bruce B. Doris, Slingerlands, NY (US); Lisa F. Edge, Watervliet, NY (US); Keith E. Fogel, Hopewell Junction, NY (US); Johnathan E. Faltermeier, Delanson, NY (US); Jinghong Li, Poughquag, NY (US); Alexander Reznicek, Troy, NY (US); Devendra K. Sadana, Pleasantville, NY (US); Bin Yang, Sunnyvale, CA (US)

(73) Assignee: INTERNATIONAL BUSINESS MACHINES CORPORATION, Armonk, NY (US)

(21) Appl. No.: 13/151,238

(22) Filed: Jun. 1, 2011

(51) Int. Cl. H01L 29/24; H01L 21/20

(52) U.S. Cl. 257/77; 438/481; 257/E21.09; 257/E29.104

(57) ABSTRACT

A method and structure are disclosed for a defect free Si:C source/drain in an NFET device. A wafer is accepted with a primary surface of {100} crystallographic orientation. A recess is formed in the wafer in such manner that the bottom surface and the four sidewall surfaces of the recess are all having {100} crystallographic orientations. A Si:C material is eptaxially grown in the recess, and due to the crystallographic orientations the defect density next to each of the four sidewall surfaces is essentially the same as next to the bottom surface. The epitaxially filled recess is used in the source/drain fabrication of an NFET device. The NFET device is oriented along the <100> crystallographic direction, and has the device channel under a tensile strain due to the defect free Si:C in the source/drain.

### BACKGROUND

The present invention relates to electronic devices of very large scale integration (VLSI) circuits. In particular, it relates to the fabrication of NFET devices with enhanced carrier mobility due to having their channel under tensile strain.

### BRIEF SUMMARY

A method and structure are disclosed for a defect free Si:C source/drain in an NFET device. A wafer is accepted with a primary surface of {100} crystallographic orientation. A recess is formed in the wafer in such manner that the bottom surface and the four sidewall surfaces of the recess are all having {100} crystallographic orientations. A Si:C material is epitaxially grown in the recess, and due to the crystallographic orientations the defect density next to each of the four sidewall surfaces is essentially the same as next to the bottom surface. The epitaxially filled recess is used in the source/drain fabrication of an NFET device. The NFET device is oriented along the <100> crystallographic direction, and has the device channel under a tensile strain due to the defect free Si:C in the source/drain.

### BRIEF DESCRIPTION OF THE SEVERAL VIEWS OF THE DRAWINGS

These and other features of the present invention will become apparent from the accompanying detailed description and drawings, wherein:

FIG. 1 is an electron micrograph of prior art epitaxial Si:C filling a recess, with visible defects next to a sidewall;

FIG. 2 schematically depicts a top view of a wafer, including a recess in an embodiment of the present invention;

FIG. 3 shows a cross sectional view a wafer, including a recess in an embodiment of the present invention;

FIG. 4 schematically depicts a top view of a wafer, including a recess in an alternate embodiment of the present invention;

FIG. 5 schematically shows an NFET device in the crystallographic orientation of an embodiment of the present invention;

FIG. 6 schematically shows a SOI NFET device in the crystallographic orientation of an embodiment of the present invention; and

FIG. 7 is an electron micrograph of epitaxial Si:C filling a recess, with the Si:C having the same low defect density next to bottom surface and the sidewalls in an embodiment of the present invention.

### DETAILED DESCRIPTION

It is understood that Field Effect Transistor-s (FET) are well known in the electronic arts. Standard components of an FET are the source, the drain, the body in-between the source and the drain, and the gate, or gate-stack. The source and drain are commonly referred to a “source/drain”, especially in cases where there may be no need to distinguish between the two. In the instant disclosure the term “source/drain” will be frequently used. The gate is overlaying the body and is capable to induce a conducting channel in the body between the source and the drain. In advanced, deeply submicron, devices the source/drain are often augmented by extensions. The gate is typically separated from the body by the gate insulator. Depending whether the “on state” current is carried by electrons or holes, the FET comes as NFET or PFET. (In different nomenclature the NFET and PFET devices are often referred to as NMOS and PMOS devices.)

The most common material of microelectronics is silicon (Si), or more broadly, Si based materials. Si based materials are various alloys of Si in the same basic technological content as Si. Such Si based materials of significance for microelectronics are, for instance, the alloys of Si with other elements of the IV-th group of the periodic table, Group IV elements, for brevity. Such alloys formed with Ge and C are silicon germanium (SiGe), and silicon carbon (Si:C). The devices in the embodiments of the present disclosure are typically of Si, and/or of Si alloyed with Ge or C. The semiconducting materials of the device bodies in representative embodiments of the invention are in a single-crystalline state.

Microelectronics progress has been essentially synonymous with decreasing feature sizes. Decreased feature sizes allow for ever higher circuit counts, and increased circuit densities for integrated circuits (IC). With decreasing dimensions, however, there is difficulty in maintaining performance improvements with each new device generation. One approach for improving performance is to increase carrier (electron and/or hole) mobilities. A promising avenue toward higher carrier mobility is to apply tensile or compressive strain in the semiconductor body regions where the channel is located. Typically, it may be preferable to have the channel of electron conduction type devices, such as NFET, under tensile strain.

Often strain is imparted on the channel by a process which commences with the recessing of the source/drain (S/D) regions of the FET device. This means that by various commonly known procedures, a recess, or void, is created in the substrate where the source/drain would be located. Next, the recess is epitaxially re-filled with a material that has a differing lattice constant than the substrate. If the lattice constant of the filling material is smaller than that of the substrate, a tensile strain will be imparted onto the device channel. A representative case known in the art is when the substrate is essentially pure Si, and the material epitaxially grown into the recess is Si:C, resulting in tensile strain in the device channel that is advantageous for NFET devices.

However, adequate quality epitaxial growth of Si:C for embedding into the source/drain region is problematic, presently lacking satisfactory solution. Along the vertical walls of the recess, the Si:C lattice structure is defected. Such defects are detrimental for several reasons, which include the followings. The defects relax the strain of a crystal lattice, consequently the strain imparted onto the channel by the Si:C is significantly lessened. The metal used for siliciding the junctions, such as Ni, forms silicide along stacking fault defects, in a phenomenon called “piping”. Furthermore, defects contribute to junction leakage in the completed devices.

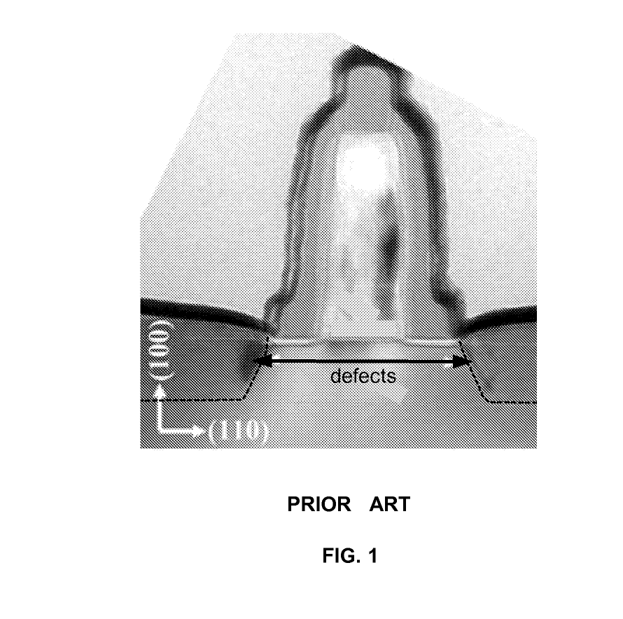

FIG. 1 is an electron micrograph of prior art epitaxial Si:C filling of a recess, which is delineated with dotted lines for visibility. Defects are clearly noticeable, and also pointed out with a double black arrow. The crystallographic orientations of the interfaces between the wafer and the Si:C, which are the sidewalls of the recess, are indicated by the white inscribing. The bottom surface of the recess is of {100}, while the sidewall surfaces are of {110}, crystallographic orientations.

For the instant disclosure investigations have been carried out for finding a solution to eliminate the defects from the Si:C that are shown in FIG. 1. It was found that the presence of defects may be independent of the parameters of the epitaxial growth. It was also found that the Si:C was growing on the bottom surface of the recess essentially defect free, while next to the vertical walls of the recess, defects were always present. The defect density was very different next to the bottom surface and next to the vertical walls.

Epitaxial deposition of Si:C, as commonly known, is an involved process. The epitaxial growth of highly-strained Si:C metastable alloys is a great challenge for conventional growth reactors, and precursors, due to the low solubility limit of carbon in silicon, the large mismatch in bond energy and length, the orientation-dependent growth rate, the precipitation, and extended defect issues.

The needed low deposition temperatures, 600° C. and below, may entail reactor and precursor background contamination levels, that may be difficult to reliably maintain. The low temperature required for sufficient substitutional carbon content may necessitate the use of separate deposition and etching steps, as no compatible in-situ etchants are available today. It is known that this separation of growth and etching: i) allows the selective removal of polycrystalline and amorphous material deposited on dielectric masking layers resulting in selective epitaxial growth without concurrent etching; ii) permits great process flexibility with respect to lowering the temperature and tailoring facets; and, iii) is required to remove the accumulating defective epitaxial material that otherwise results in polycrystalline or amorphous growth character. In the course of the present work it was found that the incorporation of C into the Si lattice may not be fully substitutional. Furthermore, it was found that this substitution may depend on crystal orientation. For instance, it was found that up to few percent of carbon, the Si:C does incorporate the C substitutionally when grown on {100} surfaces. The notation of Miller indices with curly brackets, such as for instance {100}, means, as customary in the art, all possible same type surfaces. For instance all the (100) kind surfaces in the just discussed case. At the same time it was found that growing Si:C with similar C concentrations that grew defect free on the {100} surfaces, on the {110} surfaces exhibited a high density of crystal defects, even having tendencies to form polycrystalline, or amorphous layers. Accordingly, it was discovered that the source of defects, as shown in FIG. 1, was may be due to different surface bonding character of {100} and {110} surfaces. It may be that when compared to growth on {100} surfaces, the {110} Si surfaces lead to changed dimerization of the surface states; also to altered chemical potentials for adsorbed and partially bonded reactants; and to the modification of step-flow growth. Another problem may be due to epi preclean, and residual oxygen and carbon atoms left behind on surfaces, that may be harder to clean from {110} surfaces then from {100} surfaces. Overall, it may be that efforts minimizing the defect density next to {110} surfaces by changing epitaxial growth parameters are less than fruitful because the problem may be inherent to the crystalline orientation of the seeding surfaces.

Embodiments of the present invention teach methods and structures in which the source/drain area recesses are produced in such manner that they have only {100} orientation surfaces, and consequently, the Si:C embedded into such recesses is essentially defect free.

In the microelectronics industry integrated circuits are fabricated on single crystal wafers. These wafers almost exclusively are oriented to have a {100} top surface. Also, every wafer has a marker somewhere on its perimeter. Typically all the equipment used in fabricating IC-s, such as photolithographic steppers for instance, is aligned with this marker. Such markers typically are notches, or flats, but other kinds are not excluded.

Through many years the microelectronics industry used markers that were along the <110> direction from the center of the wafer. The notation of Miller indices with “< >” brackets, such as for instance <110>, means, as customary in the art, all possible same type directions. For instance all the [100] kind directions in the just discussed case. As it developed through the years, the processing equipment aligned to the <110> direction markers lead to fabrication of FET devices that had their channels in the <110> direction, with device current flowing in the <110> direction, as well. As far as the source/drain recesses are concerned they are naturally aligned with the device channel and current direction. Accordingly, all the vertical walls of a rectangular recess had {110} orientation surfaces. And such orientation, as disclosed just above, may be the source of the detrimental defects in the epitaxial Si:C.

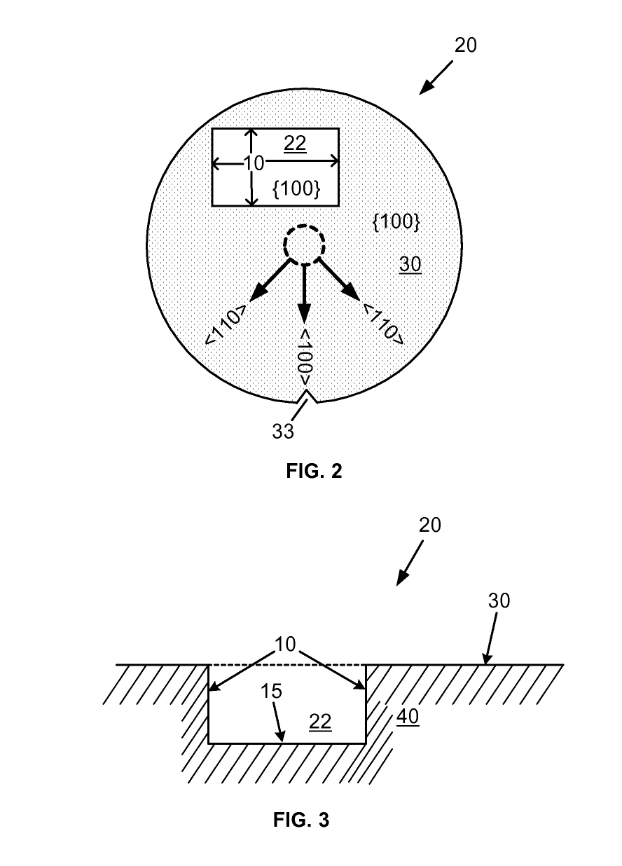

FIG. 2 schematically depicts a top view of a wafer, including a recess in an embodiment of the present invention. The figure shows a wafer 20 of a Si containing semiconductor material, which in representative embodiments of the invention may be essentially pure Si. The wafer has a primary surface 30 that is of {100} crystallographic orientation. Relative to the center of the wafer various directions, such as <100> and <110>, are indicated with arrows. In representative embodiments of the present disclosure the marker 33, shown in the figure as a notch, now is placed along the <100> direction, in contrast with the customary industry standard.

Aligning the fabrication equipment in the customary manner to the marker, now placed along the <100> direction, and fabricating a recess 22 in the customary manner, results, as shown in the figure, in a recess aligned in the customary manner to the marker, but now with all {100} surfaces. With the simple changing of the marker position, and possibly with no modification at all needed in the processing equipment, not only the bottom surface of the recess, but also all four sidewall surfaces 10 of the rectangular recess are now of {100} orientation.

FIG. 3 shows a cross sectional view of the wafer 20, including the recess 22 in an embodiment of the present invention. The recess has its bottom surface 15 vertically offset relative to the primary surface 30 of the wafer with {100} alignment, and has the vertical wall surfaces 10 also of {100} alignment. The wafer itself, includes a Si-containing semiconductor material 40, which typically is essentially pure Si.

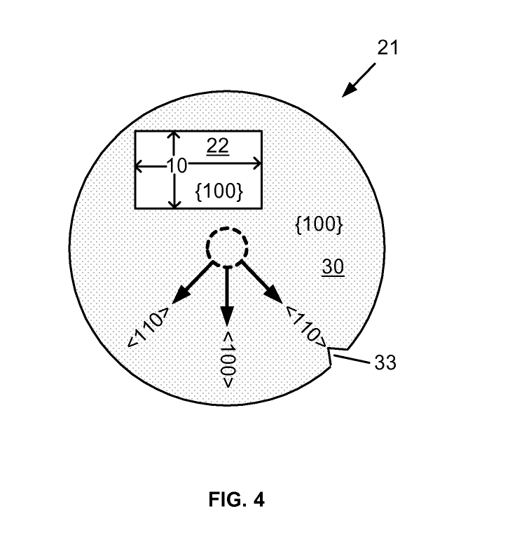

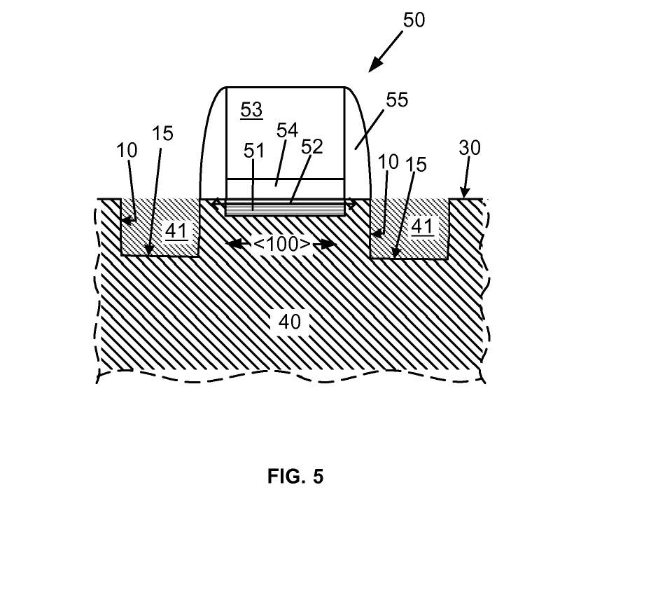

FIG. 4 schematically depicts a top view of a wafer, including a recess in an alternate embodiment of the present invention. This figure shows again a wafer 21, which in all aspects is the same as the wafer 20 of FIG. 1, with the exception of the location of the marker 33. In this representative embodiments of the present disclosure the marker is located at its customary location along the <110> direction. In the depicted representative embodiments of the present disclosure the recess 22 is rotated by about 45° relative to the marker 33, and in this manner it still has each of its four sidewall surfaces 10 of {100} crystallographic orientation. The bottom surface 15 of the recess 15 remains of {100} crystallographic orientation, as well, since its orientation does not depend on the location of the marker. In the embodiment depicted in FIG. 4, the manufacturing equipment may have to be altered, for accomplishing the 45° rotation of the recess 22 relative to the marker 33. But, in either case, in the representative embodiments of the present disclosure shown either in FIG. 2, or FIG. 4, the aim of presenting only {100} surfaces as seeds for the epitaxial growth of Si:C has been accomplished.

In FET device fabrication for representative embodiment of the present invention, the properly oriented recess 22 is useful when it is filled up with epitaxially grown Si:C. Epitaxial growth is a known technique of the VLSI fabrication art. In describing a structure, the adjective “epitaxial” is typically used to indicate that a particular material has been epitaxially grown. The structural consequence of epitaxial deposition is that the deposited material and the host material, at their common interface, have the same symmetry and crystalline orientation. They are in matching crystalline continuity. Further terms that may be used, such as “epitaxial relation”, “epitaxially”, “epitaxy”, “epi”, “epitaxial growth” etc. carry their customary usage, namely crystalline continuity across the interface. Typical techniques used in epitaxy may include molecular beam epitaxy (MBE), chemical vapor deposition (CVD), ultra high vacuum CVD (UHCVD), rapid thermal CVD (RTCVD), or further known methods.

FIG. 5 schematically shows an NFET device in the crystallographic orientation as is typical for an embodiment of the present invention. This figure depicts a representative embodiment of the present invention where due to the advantageous crystallographic orientation, the essentially defect free embedded Si:C in the source/drain region is used in an NFET device 50. The NFET is shown with it standard components, such as the gate, or gate stack 53, the gate insulator 54, sidewall spacers 55. It is understood that FIG. 5, as all figures, is only a schematic representation. As known in the art, there may be many more, or less, elements in the structures than presented in the figures, but these would not affect the scope of the embodiments of the present invention. It is also understood that in addition to the elements of the embodiments of the invention, the figures may, or may not, show other elements that are standard components of FET devices, for instance, source/drain extensions.

The single crystalline Si:C 41, which was epitaxially grown in the recess that was produced in the source/drain region, is in matching crystalline continuity with the wafer material 40. According to typical embodiment of the present invention the recess was so produced that its bottom surface 15 is vertically offset relative to the primary surface 30, and it has four sidewall surfaces 10. The cross sectional figure can obviously show only two of the sidewall surfaces 10. The bottom surface 15 and the four sidewall surfaces 10 all have {100} crystallographic orientations. The result of such orientation is that the single crystalline Si:C 41 has essentially the same defect density next to each of the four sidewall surfaces 10 as next to the bottom surface 15. And this defect density is characteristic of good quality epitaxy, which is very low, maybe orders of magnitude less than when sidewall surfaces are of {110} crystallographic orientations.

Having the Si:C embedded with the crystallographic orientation as shown in FIG. 5, entails naturally that the NFET device 50 itself is oriented in such a way that the device channel 51, which carries the device current 52, symbolically shown as a double ended arrow, is essentially in the <100> crystallographic direction. The essentially defect free Si:C 41 embedded in the source/drain regions, is imparting significant tensile strain onto the channel 51.

The NFET device 50 processed with the essentially defect free embedded Si:C 41 may have been fabricated on a wafer 20 with a marker 33 along the <100> direction. Or, in an alternate representative embodiment of the present invention on a wafer 21 that has a marker 33 along the <110> direction, but in this case with the NFET device 50 being rotated by about 45° relative to the marker 33.

The doping of the embedded Si:C in a typical embodiment of the present invention may be done by in-situ doping with P during the epitaxial growth. However, other dopants, for instance As or Sb, or other doping methods, for instance implantations, are included without limitation. The source/drain extensions, not shown in the figures, if present in the NFET, may be without limitation fabricated by any known method of the art, in any of the representative embodiments of the present invention.

The C concentration in the embedded Si:C 41 may be in the range of 0.3% and 5%, with 0.5% to 3% being typical for representative embodiments of the present invention.

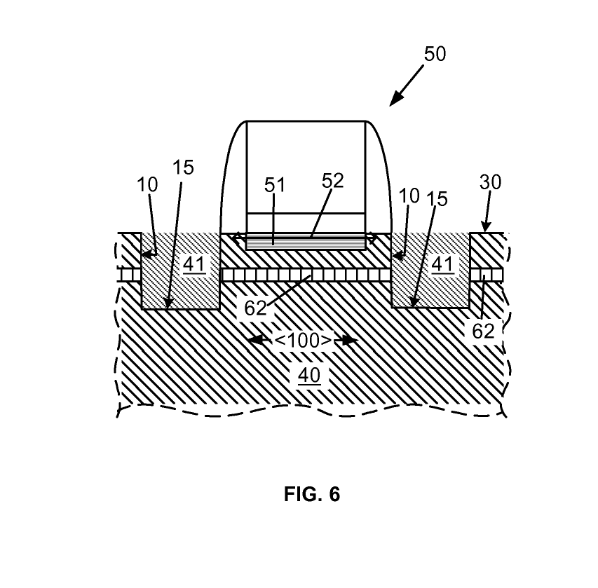

FIG. 6 schematically shows an NFET device, characterized as a semiconductor in insulator (SOI) NFET, in the crystallographic orientation of an embodiment of the present invention. The difference with the NFET shown in FIG. 5 is only that here the NFET 50 is an SOI device. FET devices that are characterized as being SOI FETs are known in the art. Such devices are formed in a layer of single crystal semiconductor material on top of an insulating layer 62. The insulating layer is typically a so called buried oxide (BOX) layer, which BOX layer, in turn, is over a silicon substrate.

As the art progresses the SOI layer becomes ever thinner. For such advanced NFET devices in a typical embodiment of the present invention the embedded single crystalline Si:C 41 may reach through the BOX layer 62 into a wafer material 40 underneath the BOX layer 62. The proper {100} orientation of the bottom 15 and four sidewall surfaces 10, yields advantage for in fabricating low defect density Si:C for SOI NFET 50 devices, as well.

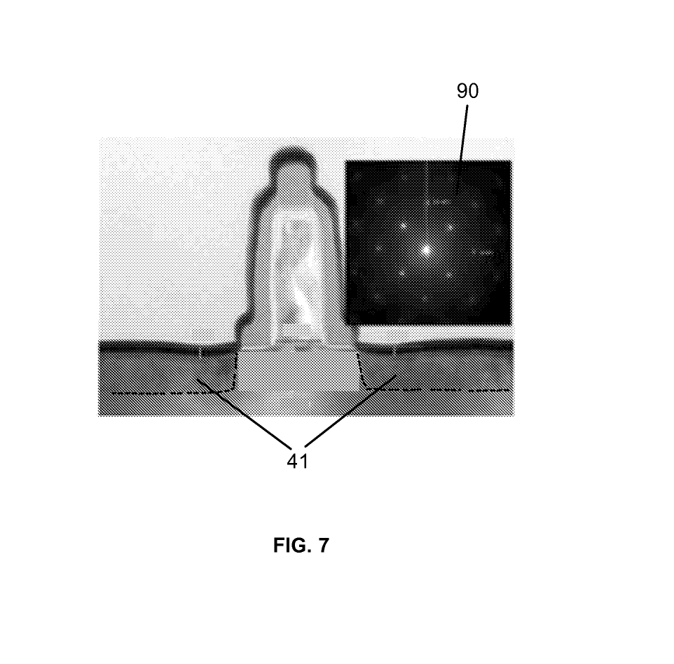

FIG. 7 is an electron micrograph of embedded epitaxial source/drain Si:C 41, for an NFET device. This embedded Si:C has same low defect density next to the bottom surface and next to the vertical walls. This NFET is in the <100> direction, with the Si:C having been grown only over {100} crystallographic surfaces, as taught by the embodiments of the present invention. A Bragg diffraction pattern picture 90, showing the perfect crystal structure of the embedded Si:C, is also shown.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as “under,” “upper”, “side,” “over”, “underneath” etc., as used herein refer to relative location and orientation of various portions of the structures with respect to one another, and are not intended to suggest that any particular absolute orientation with respect to external objects is necessary or required.

The foregoing specification also describes processing steps. It is understood that the sequence of such steps may vary in different embodiments from the order that they were detailed in the foregoing specification. Consequently, the ordering of processing steps in the claims, unless specifically stated, for instance, by such adjectives as “before”, “ensuing”, “after”, etc., does not imply or necessitate a fixed order of step sequence.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art. The scope of the invention is defined by the appended claims.

1. A method, comprising:
accepting a wafer having a primary surface of {100} crystallographic orientation, wherein said wafer comprises a Si-containing semiconductor material;
forming a recess in said wafer, wherein said recess has a bottom surface vertically offset relative to said primary surface and four sidewall surfaces, wherein said bottom surface and said four sidewall surfaces all have {100} crystallographic orientations;
eptaxially growing a Si:C material in said recess, wherein said Si:C material has a defect density next to each of said four sidewall surfaces and next to said bottom surface, wherein due to said crystallographic orientations, said defect density next to each of said four sidewall surfaces is essentially the same as next to said bottom surface; and
using said growing of Si:C in the fabrication of an NFET device, wherein said NFET device has a device channel capable of carrying a device current, wherein said device current flows essentially along the <100> crystallographic direction, and said device channel is under a tensile strain due to said growing of Si:C.

2. The method of claim 1, wherein said method further comprises forming a marker in said wafer along the <100> direction.

3. The method of claim 1, wherein said method further comprises forming a marker in said wafer along the <110> direction, and rotating said NFET device relative to said marker by about 45°.

4. The method of claim 1, wherein said method further comprises selecting said wafer to be an SOI wafer having a BOX layer.

5. The method of claim 4, wherein said method further comprises forming said recess in such manner to penetrate through said BOX layer into a substrate underneath said BOX layer.

6. The method of claim 1, wherein in said growing of Si:C, selecting the C concentration to between 0.3% and 5%.

7. The method of claim 1, wherein said method further comprises selecting said Si-containing semiconductor material to be essentially pure Si.

8. A structure, comprising:
a wafer having a primary surface of {100} crystallographic orientation, wherein said wafer comprises a Si-containing semiconductor material;
single crystalline Si:C in matching crystalline continuity with said wafer, wherein said single crystalline Si:C is filling a recess in said wafer, wherein said recess has a bottom surface vertically offset relative to said primary surface and has four sidewall surfaces, wherein said bottom surface and said four sidewall surfaces all have {100} crystallographic orientations;
wherein said single crystalline Si:C has a defect density next to each of said four sidewall surfaces and next to said bottom surface, wherein due to said crystallographic orientations, said defect density next to each of said four sidewall surfaces is essentially the same as next to said bottom surface; and
wherein said single crystalline Si:C is comprised by an NFET device, wherein said NFET device has a device channel capable of carrying a device current essentially in the <100> crystallographic direction, and said single crystalline Si:C imparts a tensile strain onto said device channel.

9. The structure of claim 8, wherein said wafer has a marker along the <100> direction.

10. The structure of claim 8, wherein said wafer has a marker along the <110> direction, and said NFET device is rotated by about 45° relative to said marker.

11. The structure of claim 8, wherein said wafer is an SOI wafer having a BOX layer.

12. The structure of claim 11, wherein said single crystalline Si:C reaches through said BOX layer into a substrate underneath said BOX layer.

13. The structure of claim 8, wherein in said single crystalline Si:C has between 0.3% and 5% of C concentration.

14. The structure of claim 8, wherein said Si-containing semiconductor material is essentially pure Si.
